(19) United States
(12) Patent Application Publication
(10) Pub. No.: US 2026/0123110 A1
(43) Pub. Date: Apr. 30, 2026

(54) LIGHT EMITTING DIODE AND LIGHT EMITTING DEVICE

(71) Applicant: QUANZHOU SANAN SEMICONDUCTOR TECHNOLOGY CO., LTD., Quanzhou (CN)

(72) Inventors: Weichun Tseng, Quanzhou (CN); Gong Chen, Quanzhou (CN); Sihe Chen, Quanzhou (CN); Tianyi Zhang, Quanzhou (CN); Xunfang Huang, Quanzhou (CN)

(21) Appl. No.: 19/375,279

(22) Filed: Oct. 31, 2025

(30) Foreign Application Priority Data
Oct. 31, 2024 (CN) 202411535515.1
Oct. 31, 2024 (CN) 202411535532.5

(51) Int. Cl. H10H 20/831; H10H 20/812; H10H 20/814; H10H 20/816; H10H 20/85; H10H 20/857

(52) U.S. Cl. CPC H10H 20/8316; H10H 20/812; H10H 20/814; H10H 20/816; H10H 20/857; H10H 20/8508

(57) ABSTRACT

A light emitting diode is provided, which includes a semiconductor stack, a first electrode, a second electrode, an insulating layer, and first and second bonding pads. The first and second electrodes are connected to the semiconductor stack. The insulating layer covers the semiconductor stack. The first and second bonding pads are respectively connected to the first and second electrodes. The first electrode includes a ring electrode and at least one strip electrode, with the strip electrode spaced apart from the ring electrode. The second electrode includes extension electrodes, and each strip electrode are located between two extension electrodes. A second opening is defined at a side of the second electrode, and a first opening is defined at an end of the strip electrode.

### CROSS-REFERENCE TO RELATED APPLICATIONS

This application claims the priority of Chinese Patent Application No. 202411535515.1, filed on Oct. 31, 2024 and Chinese Patent Application No. 202411535532.5, filed on Oct. 31, 2024, which are herein incorporated by reference in their entireties.

### TECHNICAL FIELD

The present disclosure relates to the field of semiconductor manufacturing technologies, and particularly to a light emitting diode (LED) and light emitting device.

### BACKGROUND

An LED is a semiconductor light emitting element, typically made from semiconductors such as GaN, GaAs, GaP, or GaAsP. A core of the LED is a PN junction with a light emitting property. The LED offers advantages, such as a higher luminous intensity, a higher efficiency, a smaller size, and a longer service life, and is considered one of the most promising light sources today. The LED is already widely used in lighting, surveillance and command systems, high-definition broadcasting, premium cinemas, office displays, interactive conferencing, virtual reality, and the like.

An ultraviolet light emitting diode (UV-LED) is a solid-state semiconductor device that can directly convert electrical energy into ultraviolet light. With technological advances, an enormous application value of UV LEDs, especially deep-ultraviolet (DUV) LEDs, has attracted intense attention in recent years, becoming a new focal point of research. At present, conventional DUV LEDs face problems such as current crowding and poor luminous uniformity. Therefore, how to solve these problems has become one of the urgent technical challenges for those skilled in the art.

### SUMMARY

In an embodiment, an LED is provided, which includes: a semiconductor stack, including: a first semiconductor layer, a light emitting layer, and a second semiconductor layer sequentially stacked in that order; a first electrode, disposed on the semiconductor stack and electrically connected to the first semiconductor layer; a second electrode, disposed on the semiconductor stack and electrically connected to the second semiconductor layer; an insulating layer, covering the semiconductor stack, the first electrode, and the second electrode, where the insulating layer defines a first opening and a second opening; a first bonding pad, disposed on the insulating layer, where the first bonding pad penetrates through the first opening and is electrically connected to the first electrode; a second bonding pad, disposed on the insulating layer, where the second bonding pad penetrates through the second opening and is electrically connected to the second electrode; in a top-down view of the LED from an upper surface of the LED toward the semiconductor stack, the first electrode includes an ring electrode and at least one strip electrode, each of the at least one strip electrode is spaced apart from the ring electrode, the second electrode includes at least two extension electrodes, the ring electrode surrounds the second electrode, each of the at least one strip electrode is located between adjacent two extension electrodes of the at least two extension electrodes, the second opening is disposed on a side of the second electrode, an end of each of the at least one strip electrode facing toward the second opening is defined as a first end, and an end of each of the at least one strip electrode facing away from the second opening is defined as a second end, at least one the first opening is disposed at the second end of each of the at least one strip electrode.

In an embodiment, a light emitting device is provided, which includes the LED as described above.

According to the LED and the light emitting device provided by the embodiments of the present disclosure, current congestion is avoided through a shape design of electrodes and a position design of openings of an insulating layer, thereby resulting in more uniform light emission from the LED and improved light emitting characteristics of the LED.

### BRIEF DESCRIPTION OF DRAWINGS

To more clearly illustrate technical solutions in embodiments of the present disclosure or in the related art, accompanying drawings that need to be used in the description of the embodiments or the related art will be briefly introduced below. Apparently, some of the accompanying drawings described below are embodiments of the present disclosure. For ordinary technicians in this field, other drawings can also be obtained based on these drawings without creative efforts.

FIG. 1 illustrates a schematic top-view structural view of a conventional LED.

FIG. 2 illustrates a schematic top-view structural view of an LED according to a first embodiment of the present disclosure.

FIG. 3 illustrates a schematic structural view of a second electrode of the LED in FIG. 2.

FIG. 4 illustrates a schematic cross-sectional structural view taken along a line A-A in FIG. 2.

FIG. 5 through FIG. 10 illustrate schematic structural diagrams corresponding to multiple stages during a manufacturing process of the LED according to the first embodiment of the present disclosure.

FIG. 11 illustrates a schematic top-view structural view of an LED according to a second embodiment of the present disclosure.

FIG. 12 illustrates a schematic structural view of a second electrode of the LED in FIG. 11.

FIG. 13 illustrates a schematic top-view structural view of an LED according to a third embodiment of the present disclosure.

FIG. 14 illustrates a schematic structural view of a second electrode of the LED in FIG. 13.

FIG. 15 illustrates a schematic top-view structural view of an LED according to a fourth embodiment of the present disclosure.

FIG. 16 illustrates a schematic structural view of a second electrode of the LED in FIG. 15.

FIG. 17 illustrates a schematic top-view structural view of an LED according to a fifth embodiment of the present disclosure.

FIG. 18 illustrates a schematic structural view of a second electrode of the LED in FIG. 17.

FIG. 19 illustrates a schematic top-view structural view of an LED according to a sixth embodiment of the present disclosure.

FIG. 20 illustrates a schematic structural view of a second electrode of the LED in FIG. 19.

### REFERENCE NUMERALS

10. Substrate; 12. Semiconductor stack; 121. First semiconductor layer; 122. Light emitting layer; 123. Second semiconductor layer; 21. First connection electrode; 22. Second connection electrode; 31. First electrode; 311. Ring electrode; 312. Strip electrode; 313-First end; 314. Second end; 32. Second electrode; 321. Starting electrode; 322. Extension electrode; 323. First side/first end; 324. Second side/second end; 325. End; 40. Insulating layer; 401. First opening; 402. Second opening; 41. First bonding pad; 42. Second bonding pad; 50. Protrusion region; 51. Protrusion structure; 60. Groove; 61. First side edge; 62. Second side edge; 63. Third side edge; 64. Fourth side edge; L1. First spacing; L2. Second spacing; L3. Third spacing; L4. Fourth spacing; S1. First minimum spacing; S2. Second minimum spacing; S3. Horizontal minimum spacing; S4. Extension length; s1. Lateral length; s2. Lateral length; s3. Lateral length.

### DETAILED DESCRIPTION OF EMBODIMENTS

In order to make the objectives, technical solutions, and advantages of the embodiments of the present disclosure clearer, the technical solutions in the embodiments of the present disclosure will be described clearly and completely below in conjunction with the accompanying drawings in the embodiments of the present disclosure. Apparently, the described embodiments are part of embodiments of the present disclosure, but not all of them. The technical features described in different implementations of the present disclosure below can be combined with each other as long as they do not conflict with each other. Based on the embodiments of the present disclosure, all other embodiments obtained by a person of ordinary skill in the art without creative efforts shall fall within the scope of protection the present disclosure.

In the description of the present disclosure, it should be understood that terms such as “center”, “lateral”, “upper”, “lower”, “left”, “right”, “vertical”, “horizontal”, “top”, “bottom”, “inner”, and “outer”, indicate orientations or positional relationships based on the orientations or positional relationships shown in the accompanying drawings. These terms are only for the convenience of describing the present disclosure and simplifying the description, rather than indicating or implying that the referred apparatus or components must have a specific orientation or be constructed and operated in a specific orientation. Therefore, these terms should not be construed as limitations to the present disclosure. Furthermore, terms “first” and “second” are used for descriptive purposes only and should not be construed as indicating or implying relative importance or implicitly indicating the quantity of the referred technical features. Thus, features defined by the terms “first” and “second” may explicitly or implicitly include one or more of such features. In the description of the present disclosure, unless otherwise specified, “multiple” means two or more. In addition, the term “includes” and any variations thereof are intended to mean “includes at least”.

### First Embodiment

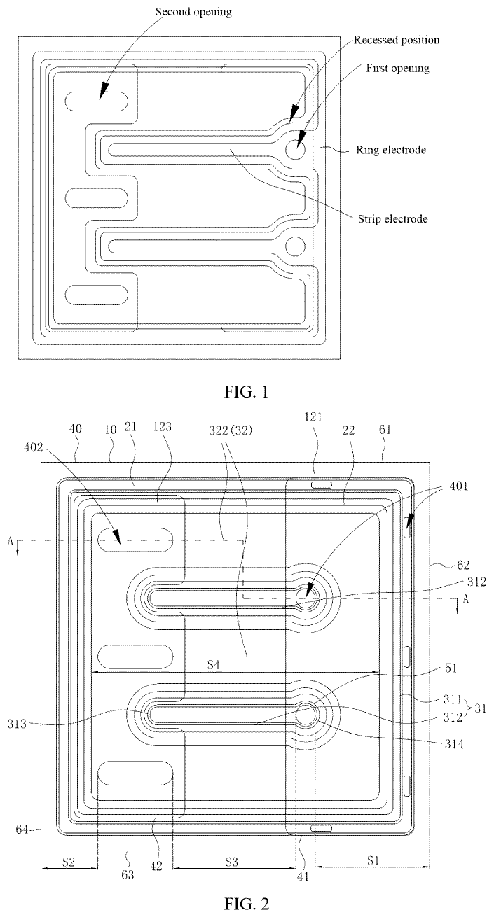

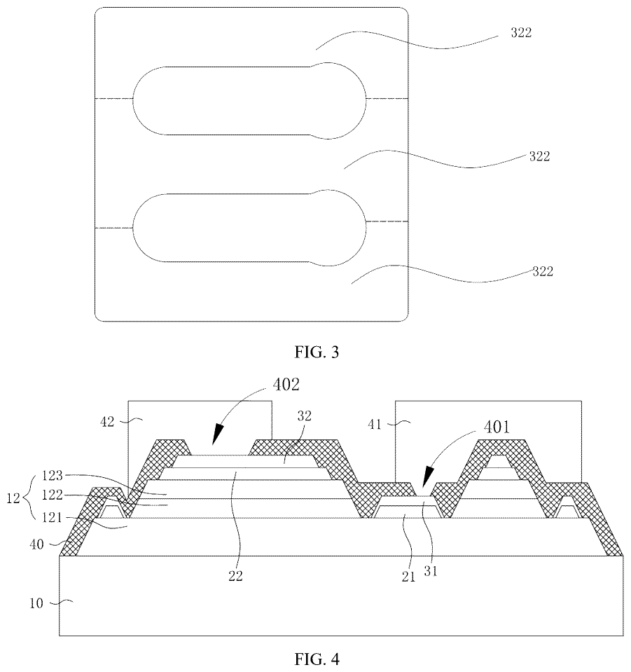

Please refer to FIG. 1 to FIG. 4, FIG. 1 illustrates a schematic top-view structural view of a conventional LED. FIG. 2 illustrates a schematic top-view structural view of an LED according to a first embodiment of the present disclosure. FIG. 3 illustrates a schematic structural view of a second electrode of the LED in FIG. 2. FIG. 4 illustrates a schematic cross-sectional structural view taken along a line A-A in FIG. 2. To achieve at least one of the aforementioned advantages or other advantages, the first embodiment of the present disclosure provides an LED. As shown in FIG. 4, the LED in the first embodiment includes a semiconductor stack 12, a first connection electrode 21, a second connection electrode 22, a first electrode 31, a second electrode 32, an insulating layer 40, a first bonding pad 41, and a second bonding pad 42.

The semiconductor stack 12 is disposed on a substrate 10. The substrate 10 may be a transparent substrate or a semi-transparent substrate. The transparent substrate or the semi-transparent substrate allows light emitted by a light emitting layer 122 of the semiconductor stack 12 to pass through the substrate 10 to a side of the substrate 10 facing away from the semiconductor stack 12. For example, the substrate 10 can be any one of a sapphire flat substrate, a patterned sapphire substrate, a silicon substrate, a silicon carbide substrate, a gallium nitride substrate, or a glass substrate. In some embodiments, the substrate 10 may be thinned or removed to form a thin-film type chip.

The semiconductor stack 12 includes a first semiconductor layer 121, the light emitting layer 122, and a second semiconductor layer 123 sequentially stacked on the substrate 10 in that order.

The first semiconductor layer 121 may be an N-type semiconductor layer, which can provide electrons to the light emitting layer 122 under an action of a power supply. In some embodiments, the first semiconductor layer 121 includes an N-type doped nitride layer. The N-type doped nitride layer may include an N-type impurity. The N-type impurity may include one or a combination of Si, Ge, and Sn. In some embodiments, the first semiconductor layer 121 is doped with Al to facilitate the LED to emit ultraviolet light.

The light emitting layer 122 may be a quantum well (QW) structure. In some embodiments, the light emitting layer 122 may be a multiple quantum well (MQW) structure, where the multiple quantum well structure includes multiple quantum well layers (i.e., well layers) and multiple quantum barrier layers (i.e., barrier layers) alternately arranged in a repeating manner, for example, a multiple quantum well structure such as GaN/AlGaN, InAlGaN/InAlGaN, or InGaN/AlGaN. Furthermore, a composition and a thickness of the well layers in the light emitting layer 122 determine a wavelength of a light generated by the light emitting layer 122. A light emission efficiency of the light emitting layer 122 can be improved by changing a depth of the multiple quantum well layers, a number of pairs of quantum well layer and quantum barrier layer, a thickness of each of pairs of quantum well layer and quantum barrier layer, and/or other characteristics in the light emitting layer 122. In some embodiments, the LED is an ultraviolet LED, and thus the light emitting layer 122 emits ultraviolet light.

The second semiconductor layer 123 may be a P-type semiconductor layer, which can provide holes to the light emitting layer 122 under the action of the power supply. In some embodiments, the second semiconductor layer 123 includes a P-type doped nitride layer. The P-type doped nitride layer may include one or more P-type impurities. The P-type impurity may include one or a combination of Mg, Zn, and Be. The second semiconductor layer 123 may have a single-layer structure or a multi-layer structure with different compositions. Furthermore, the arrangement of the semiconductor stack 12 is not limited thereto and may be selected according to actual needs. In some embodiments, to improve light emission efficiency of the LED, the second semiconductor layer 123 may be appropriately thinned to reduce epitaxial light absorption. A thickness of the second semiconductor layer 123 is in a range of 1 nm to 100 nm, preferably in a range of 5 nm to 50 nm, and more preferably in a range of 5 nm to 10 nm.

The first connection electrode 21 is disposed on the semiconductor stack 12 and electrically connected to the first semiconductor layer 121. The first connection electrode 21 may have a single-layer structure, a double-layer structure, or a multi-layer structure, for example, a stacked structure, such as, Ti/Al, Ti/Al/Ti/Au, Ti/Al/Ni/Au, or V/Al/Pt/Au. In some embodiments, the first connection electrode 21 may be directly formed on a mesa of the semiconductor stack 12, as such, since the first semiconductor layer 121 has a relatively high Al component, the first connection electrode 21 forms an alloy after being deposited on the mesa and undergoing high-temperature fusion, thereby forming an excellent ohmic contact with the first semiconductor layer 121.

The second connection electrode 22 is disposed on the semiconductor stack 12 and electrically connected to the second semiconductor layer 123. The second connection electrode 22 may be made of a transparent conductive material or a metal material, and a specific material of the second connection electrode 22 can be adaptively determined according to a doping condition of a surface layer (such as a p-type GaN surface layer) of the second semiconductor layer 123. In some embodiments, the second connection electrode 22 is made of the transparent conductive material, which may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the present disclosure are not limited thereto.

The first electrode 31 is connected to the first connection electrode 21. The first electrode 31 not only serves for current spreading but also protects the underlying first connection electrode 21 and serves functions such as support and elevation. In an embodiment, the first electrode 31 completely covers the first connection electrode 21 to prevent metal precipitation from the first connection electrode 21, for example, to prevent metal Al precipitation. A material of the first electrode 31 may be one or more selected from the group consisting of Cr, Pt, Au, Ni, Ti, and Al. In a specific embodiment, a surface metal of the first electrode 31 is a Ti metal layer or a Cr metal layer, so that the first electrode 31 forms a stable adhesion relationship with a structural layer adjacent to the first electrode 31.

The second electrode 32 is connected to the second connection electrode 22. A material of the second electrode 32 may be one or more selected from the group consisting of Cr, Pt, Au, Ni, Ti, and Al. In an embodiment, a surface metal of the second electrode 32 is a Ti metal layer or a Cr metal layer, so that the second electrode 32 forms a stable adhesion relationship with a structural layer adjacent to the second electrode 32.

The insulating layer 40 covers the semiconductor stack 12, the first electrode 31, and the second electrode 32. The insulating layer 40 defines a first opening 401 and a second opening 402. The first electrode 31 is exposed from the first opening 401, and the second electrode 32 is exposed from the second opening 402. The insulating layer 40 has different effects depending on its location. For example, when the insulating layer 40 covers a sidewall of the semiconductor stack 12, the insulating layer 40 can be used to prevent electrical connection between the first semiconductor layer 121 and the second semiconductor layer 123 due to leakage of a conductive material, thereby reducing short-circuit abnormalities in the LED, but the embodiments of the present disclosure are not limited thereto. A material of the insulating layer 40 includes a non-conductive material. The non-conductive material is an inorganic material or a dielectric material. The inorganic material may include silica gel. The dielectric material includes an electrical insulating material, such as aluminum oxide, silicon nitride, silicon oxide, titanium oxide, or magnesium fluoride. For example, the insulating layer 40 may be one or more selected from the group consisting of silicon dioxide, silicon nitride, titanium oxide, tantalum oxide, niobium oxide, and barium titanate. The insulating layer 40 may be, for example, a distributed Bragg reflector (DBR) formed by repeatedly stacking two materials with different refractive indices.

The first bonding pad 41 is disposed on the insulating layer 40, and the first bonding pad 41 penetrates through the first opening 401 and is electrically connected to the first electrode 31 via the first opening 401.

The second bonding pad 42 is disposed on the insulating layer 40, and the second bonding pad 42 penetrates through the second opening 402 and is electrically connected to the second electrode 32. The first bonding pad 41 and the second bonding pad 42 may be metal bonding pads, which can be formed simultaneously in a same process using a same material, and thus the first bonding pad 41 and the second bonding pad 42 may have a same layer structure. The first bonding pad 41 and the second bonding pad 42 are spaced apart on the insulating layer 40.

In a top-down view of the LED from an upper surface of the LED toward the semiconductor stack 12, as shown in FIG. 2, the first electrode 31 includes a ring electrode 311 and at least one strip electrode 312. In an illustrated embodiment, as shown in FIG. 2, a number of the at least one strip electrode 312 is two. Each of the at least one strip electrode 312 and the ring electrode 311 are spaced apart, meaning they do not overlap in the plan view of the LED. In some embodiments, considering the need to improve light emission efficiency, the second semiconductor layer 123 is appropriately thinned to reduce light absorption, but this reduces the lateral current spreading capability between semiconductor stacks 12. The reduction in lateral spreading capability and the higher Al component in a deep ultraviolet LED both cause an increase in contact voltage on an N side of the LED. Therefore, an N-side electrode (i.e., the first electrode 31) can be designed to surround a periphery of the LED, to thereby form the ring electrode 311, and the at least one strip electrode 312 can be added inside a light emitting region to reduce voltage.

The second electrode 32 includes at least two extension electrodes 322. In an illustrated embodiment, as shown in FIG. 2 and FIG. 3, a number of the at least two extension electrodes 322 is three. The ring electrode 311 surrounds the second electrode 32, and the at least two extension electrodes 322 are located inside the ring electrode 311. Each strip electrode 312 is located between adjacent two extension electrodes 322. Taking FIG. 2 as an example, one strip electrode 312 is disposed between upper and lower two extension electrodes 322. The second opening 402 is disposed at a side of the second electrode 32. In some embodiments, the second opening 402 is at least two in number, and each extension electrode 322 is defined with one second opening 402 therein. An end of the strip electrode 312 close to the second opening 402 is defined as a first end 313, and an end of the strip electrode 312 away from the second opening 402 is defined as a second end 314. Taking FIG. 2 as an example, the first end 313 is a left end of the strip electrode 312, and the second end 314 is a right end of the strip electrode 312. At least one first opening 401 is disposed at the second end 314 of the strip electrode 312. Thereby, current crowding is avoided, making the light emission of the LED more uniform and improving the light emitting characteristics of the light emitting diode.

As shown in FIG. 1, in a conventional LED, a strip electrode is connected to a ring electrode and extends inward from the ring electrode, and a first opening of an insulating layer is disposed at a connection position between the strip electrode and the ring electrode. Since this connection position is inherently a current convergence zone, and the first opening of the insulating layer is located here, it further confines a current near the first opening, leading to current crowding and poor light emission uniformity. To solve this problem, the present disclosure disconnects the strip electrode 312 from the ring electrode 311, and simultaneously positions the first opening 401 at the end of the strip electrode 312 away from the second opening 402. On one hand, the first opening 401 is positioned at the location where the strip electrode 312 is disconnected from the ring electrode 311; on the other hand, the first opening 401 and the second opening 402 are distributed on different sides of the strip electrode 312, thereby avoiding current crowding and making the light emission of the LED more uniform. In some embodiments, a number of the at least one strip electrode 312 is a, and a number of the at least two extension electrodes 322 is b, and b=a+1. That is, the number of the at least two extension electrodes 322 is one more than the number of the at least one strip electrode 312, so that each strip electrode 312 can be sandwiched between two extension electrodes 322, which is beneficial for more uniform current distribution.

In some embodiments, as shown in FIG. 2, in a top-down view of the LED from an upper surface of the LED toward the semiconductor stack 12, two sides of one of the adjacent two extension electrodes 322 of the at least two extension electrodes 322 are respectively connected to two sides of the other of the adjacent two extension electrodes 322 of the at least two extension electrodes 322 to form a closed-loop pattern. Specifically, a number of the closed-loop pattern is two, and the two closed-loop patterns are connected vertically to form a shape formed by two rectangles sharing one common side. Through the above design, the ring electrode 311 surrounds the second electrode 32 and the second electrode 32 surrounds the strip electrode 312, making distances from multiple positions of the first electrode 31 to multiple positions of the second electrode 32 more unified, which is beneficial for more uniform current distribution, making the light emission of the LED more uniform, and further improving the light emitting characteristics of the LED.

In the top-down view of the LED from the upper surface of the LED toward the semiconductor stack 12, an area ratio of the first connection electrode 21 to the second connection electrode 22 is not greater than 1:4. Increasing an area of the second connection electrode 22 can, on one hand, increase lateral current spreading capability and reduce voltage; on the other hand, it can reduce current density and improve aging stability.

In some embodiments, in the top-down view of the LED from the upper surface of the LED toward the semiconductor stack 12, the first opening 401 and the second opening 402 have a minimum horizontal spacing S3. The minimum horizontal spacing S3 is not less than one-quarter of an extension length S4 of the extension electrode 322. In some embodiments, the minimum horizontal spacing S3 between the first opening 401 and the second opening 402 is not less than 70 μm, such as, in a range of 90 μm to 130 μm, for example, it can be 100 μm, 110 μm, or 120 μm. This minimum horizontal spacing S3, as shown in the FIG. 2, refers to a minimum spacing between the first opening 401 and the second opening 402 in a horizontal direction, not an oblique minimum spacing between them. Ensuring a certain spacing S3 between the first opening 401 and the second opening 402 improves an overall current uniformity of the LED and avoids current crowding.

In some embodiments, each strip electrode 312 is provided with a protruding structure 51 at the second end 314. At least one first opening 401 is defined in the protruding structure 51. Positioning the at least one first opening 401 at the protruding structure 51 ensures sufficient current conduction channels at the first opening 401, increases current conduction, and avoids current crowding at the first opening 401.

In some embodiments, at least one first opening 401 is defined in the ring electrode 311. Distributing the first openings 401 on both the ring electrode 311 and the strip electrode 312 can further improve the light emission uniformity on a side of the first electrode 31. In some embodiments, as shown in FIG. 2, in the top-down view of the LED from the upper surface of the LED toward the semiconductor stack 12, the LED has a first side edge 61, a second side edge 62, a third side edge 63, and a fourth side edge 64 connected sequentially in that order. In this embodiment, the first side edge 61, the second side edge 62, the third side edge 63, and the fourth side edge 64 are an upper side, a right side, a lower side, and a left side, respectively. The first side edge 61 and the third side edge 63 are oppositely disposed. The second side edge 62 and the fourth side edge 64 are oppositely disposed. The second opening 402 is closer to the fourth side edge 64 compared to the first opening 401. The first opening 401 is closer to the second side edge 62 compared to the second opening 402. That is, the first opening 401 and the second opening 402 are respectively disposed near opposite sides of the LED, thereby avoiding current crowding and improving the light output uniformity of the LED.

In some embodiments, in the top-down view of the LED from the upper surface of the LED toward the semiconductor stack 12, a first minimum spacing S1 from one first opening 401 located within the strip electrode 312 to the second side edge 62 is less than ½ of the extension length S4 of the extension electrode 322 and greater than 1/10 of the extension length S4 of the extension electrode 322. A second minimum spacing from one second opening 402 to the fourth side edge 64 is less than ½ of the extension length S4 of the extension electrode 322 and greater than 1/15 of the extension length S4 of the extension electrode 322. The first minimum spacing S1 is greater than the second minimum spacing S2.

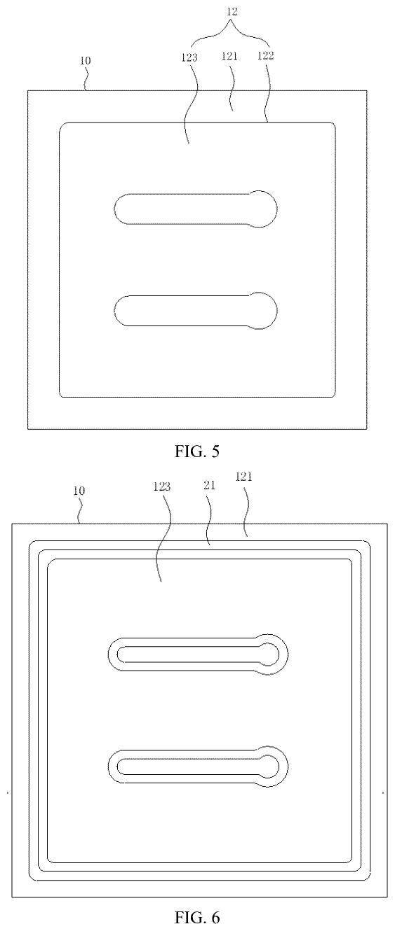

Please refer to FIG. 5 to FIG. 10, FIG. 5 through FIG. 10 illustrate schematic structural diagrams corresponding to multiple stages during a manufacturing process of the LED according to the first embodiment of the present disclosure.

First, referring to FIG. 5, the semiconductor stack 12 including the first semiconductor layer 121, the light emitting layer 122, and the second semiconductor layer 123 is formed on the substrate 10. Then, etching is performed from the second semiconductor layer 123 toward the first semiconductor layer 121 until the first semiconductor layer 121 is exposed.

Next, referring to FIG. 6, the first connection electrode 21 is formed on the first semiconductor layer 121.

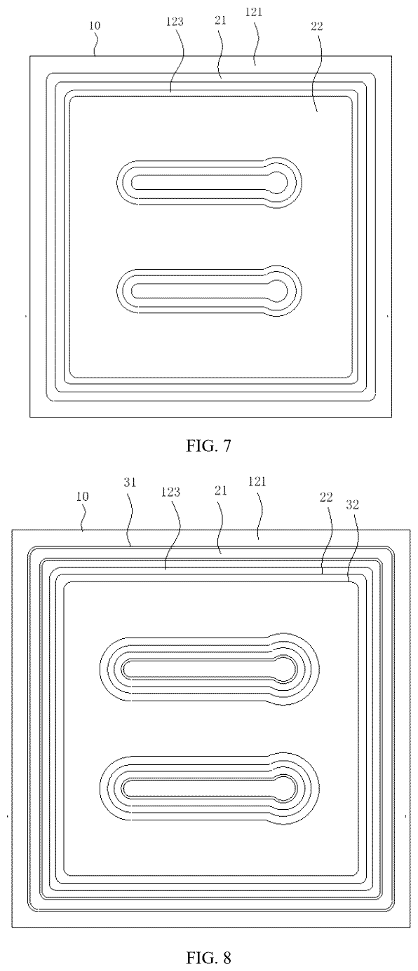

Then, referring to FIG. 7, the second connection electrode 22 is formed on the second semiconductor layer 123.

Subsequently, referring to FIG. 8, the first electrode 31 covering the first connection electrode 21 is provided at the first connection electrode 21, and the second electrode 32 is provided on the second connection electrode 22.

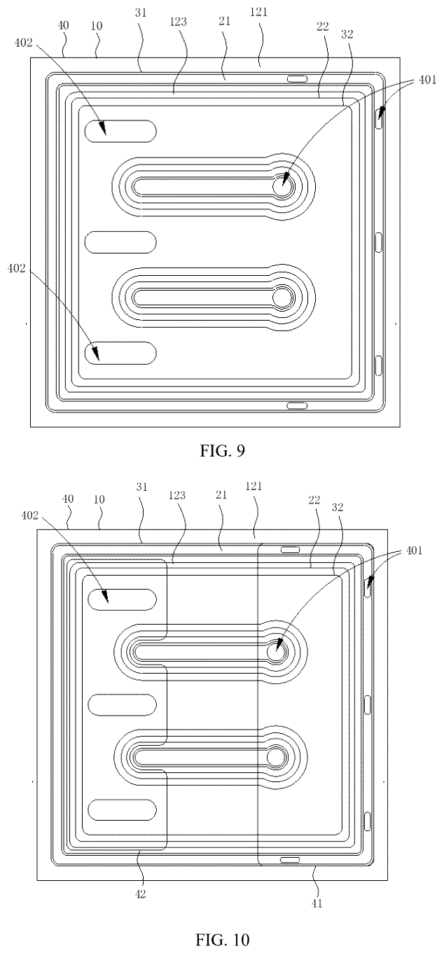

Next, referring to FIG. 9, the insulating layer 40 is formed on the semiconductor stack 12, the first electrode 31, and the second electrode 32. The insulating layer 40 is defined with first openings 401 and second openings 402. The first openings 401 and the second openings 402 are used to expose the first electrode 31 and the second electrode 32, respectively, to facilitate the electrical connection of subsequent bonding pads. The insulating layer 40 mainly serves to provide electrical isolation and protect internal components.

Finally, referring to FIG. 10, the first bonding pad 41 and the second bonding pad 42 are formed on the insulating layer 40. The first bonding pad 41 is electrically connected to the first electrode 31 through the first openings 401, and the second bonding pad 42 is electrically connected to the second electrode 32 through the second openings 402.

### Second Embodiment

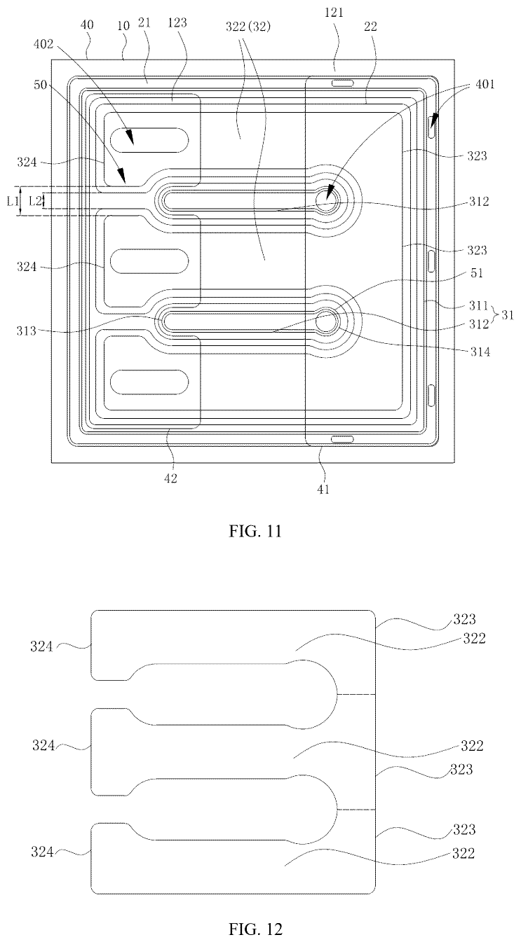

Please refer to FIG. 11, FIG. 11 illustrates a schematic top-view structural view of an LED according to the second embodiment of the present disclosure. Compared to the LED of the first embodiment shown in FIG. 2, the same parts will not be elaborated upon further. Main differences between this embodiment and other embodiments are as follows: each extension electrode 322 has a first side 323 away from the second opening 402 and a second side 324 close to the second opening 402. The first side 323 and the second side 324 are oppositely disposed. The second opening 402 is disposed near the second side 324. Taking FIG. 12 as an example, the first side 323 is a right side of the extension electrode 322, and the second side 324 is a left side of the extension electrode 322. First sides 323 of adjacent two extension electrodes 322 are connected to each other to form an integrated electrode. A first spacing L1 exists between second sides 324 of adjacent two extension electrodes 322. A range of the first spacing L1 is not less than 10 μm, preferably not less than 20 μm, for example, it can be 25 μm, 30 μm, or 35 μm. By spacing apart the second sides 324 of adjacent two extension electrodes 322 and positioning the second opening 402 at the second sides 324, it is also possible to avoid placing the second openings 402 in the current convergence zone, further preventing current from being confined near the second openings 402, which leads to current crowding and poor light emission uniformity. Theoretically, current interruption can be achieved as long as the first spacing L1 is greater than 0. However, due to limitations in actual manufacturing capabilities, it cannot be made too small. Furthermore, if the first spacing L1 is too small, such as less than 5 μm, an area of the first connection electrode 21 becomes smaller, which would cause an increase in voltage.

In some embodiments, in the top-down view of the LED from the upper surface of the LED toward the semiconductor stack 12, portions of the second connection electrode 22 respectively located below second sides 324 of adjacent two extension electrodes 322 have a second spacing L2 between them. A range of the second spacing L2 is not less than 5 μm, preferably not less than 10 μm, for example, it can be 15 μm, 20 μm, or 25 μm. This ensures that the portions of the second connection electrode below the second openings 402 are disconnected, further avoiding current confinement near the second openings 402 and preventing current crowding. Theoretically, current interruption can be achieved as long as the second spacing L2 is greater than 0. However, due to limitations in actual manufacturing capabilities, it cannot be made too small. Furthermore, if the second spacing L2 is too small, such as less than 5 μm, the area of the first connection electrode 21 becomes smaller, which would cause an increase in voltage. In some embodiments, the first spacing L1 is greater than the second spacing L2.

In some embodiments, in the top-down view of the LED from the upper surface of the LED toward the semiconductor stack 12, an end of the extension electrode 322 has a protruding region 50. The protruding region 50 protrudes toward a direction of another extension electrode 322 adjacent to the extension electrode 322 where the protruding region 50 is located. Compared to the conventional LED shown in FIG. 1, which has a recessed design (i.e., the recessed position in FIG. 1) at an end of a corresponding extension electrode due to considerations of current crowding and current spreading, this embodiment features the protruding region 50, thereby increasing an area of the second connection electrode 22. In the top-down view of the LED from the upper surface of the LED toward the semiconductor stack 12, a contact area between the second connection electrode 22 and the second semiconductor layer 123 is at least 45% of an area of the LED. In an embodiment, the contact area between the second connection electrode 22 and the second semiconductor layer 123 is 45% to 70% of the area of the LED. In another embodiment, the contact area between the second connection electrode 22 and the second semiconductor layer 123 is 45% to 65% of the area of the LED. By increasing the area of the second connection electrode 22, the lateral current spreading capability can be increased, reducing voltage; on the other hand, the current density can be reduced, improving aging stability.

Due to the provision of the protruding region 50, in the top-down view of the LED from the upper surface of the LED toward the semiconductor stack 12, an area of the second semiconductor layer 123 is at least 55% of the area of the LED. In an embodiment, the area of the second semiconductor layer 123 is 55% to 75% of the area of the LED. In another embodiment, the area of the second semiconductor layer 123 is 55% to 70% of the area of the LED. By increasing the area of the second semiconductor layer 123, the light output brightness can be improved on one hand, and on the other hand, it is beneficial to increase the contact area of the second connection electrode 22, improving performance. In some embodiments, considering the need to improve light emission efficiency, the second semiconductor layer 123 is appropriately thinned to reduce light absorption, but this reduces the lateral current spreading capability between the semiconductor stacks 12, making it difficult to lower the voltage. Through the design of the present disclosure, the area of the second semiconductor layer 123 can be increased, thereby ensuring lateral current spreading capability while thinning the second semiconductor layer 123, preventing an increase in voltage.

### Third Embodiment

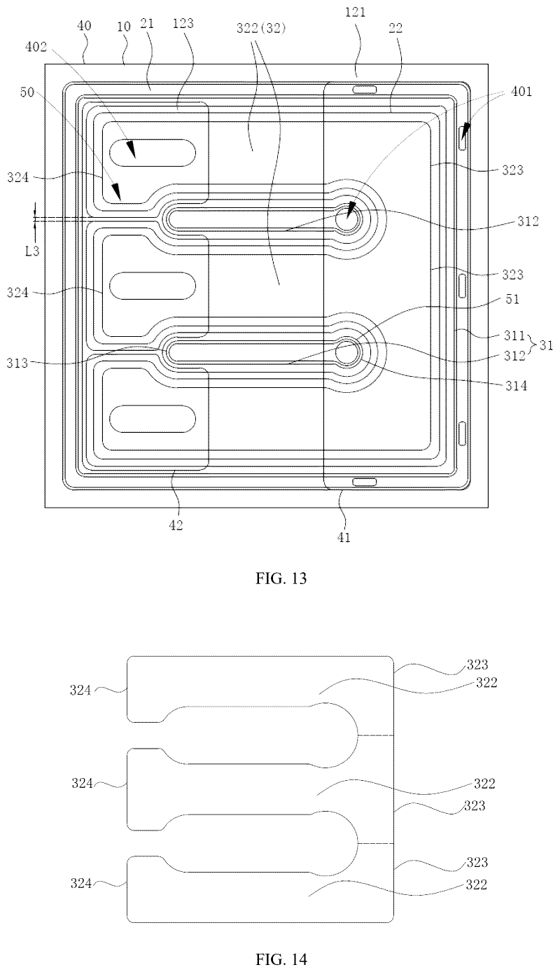

Please refer to FIG. 13, FIG. 13 illustrates a schematic top-view structural view of an LED according to the third embodiment of the present disclosure. Compared to LEDs of other embodiments, main difference of this embodiment is: in the top-down view of the LED from the upper surface of the LED toward the semiconductor stack 12, portions of the second semiconductor layer 123 respectively located below the second sides 324 of adjacent two extension electrodes 322 have a third spacing L3 between them. That is, in the second embodiment, the portions of the second semiconductor layer 123 below the second sides 324 of the adjacent two extension electrodes 322 are connected to each other, thereby retaining more area of the second semiconductor layer 123 and preventing an increase in voltage. In this embodiment, the portions of the second semiconductor layer 123 below the second sides 324 of the adjacent two extension electrodes 322 are disconnected, thereby further enhancing current spreading performance. In an embodiment, the second spacing L2 is greater than the third spacing L3.

### Fourth Embodiment

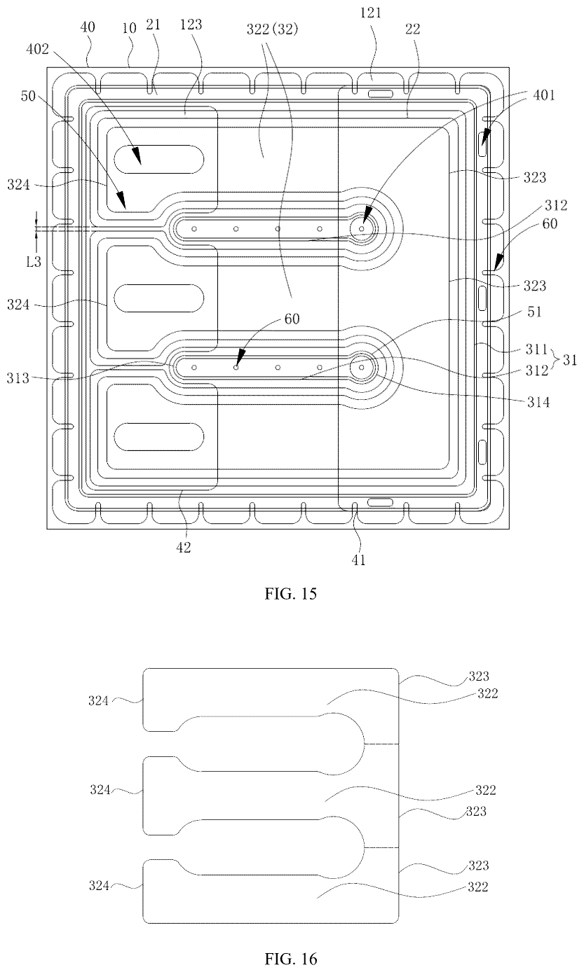

In some embodiments, as shown in FIG. 15, FIG. 15 illustrates a schematic top-view structural view of an LED according to the fourth embodiment of the present disclosure. Main difference of the LED in this embodiment is: the LED in the fourth embodiment further includes grooves 60. The grooves 60 are formed inside and on an outer sidewall of the first semiconductor layer 121. The grooves 60 extend from the first semiconductor layer 121 toward the substrate 10. The grooves 60 can extend downward from an upper surface of the first semiconductor layer 121 for an appropriate distance without penetrating the first semiconductor layer 121 to an upper surface of the substrate 10. The grooves 60 can also extend downward from the first semiconductor layer 121 to the upper surface of the substrate 10, which means that the grooves 60 completely penetrate the first semiconductor layer 121. The first connection electrode 21 covers a sidewall and a bottom of at least one groove 60, and also covers part (such as the upper surface of the first semiconductor layer 121) of a planar area of the first semiconductor layer 121, forming ohmic contact with the first semiconductor layer 121. By arranging the first connection electrode 21 to cover the sidewall of the at least one groove 60, the effect of current shunting and lateral injection into the first semiconductor layer 121 can be achieved, enhancing the lateral propagation of current within the first semiconductor layer 121 and reducing the operating voltage.

Furthermore, due to a waveguide effect, light in existing LEDs forms oscillating reflections between the light emitting layer 122 and the substrate 10, causing light to be absorbed within the semiconductor layer. The present disclosure, by having the first connection electrode 21 extend deep into the groove 60, blocks the waveguide effect at the groove 60, allowing the first contact electrode 21 to reflect more light emitted by the light emitting layer 122 toward the exterior, thereby improving the light extraction efficiency of the LED. In some embodiments, a sidewall of the groove 60 is inclined. Preferably, an inclination angle of the sidewall of the groove 60 is less than or equal to 60°. More preferably, the inclination angle of the sidewall of the groove 60 is in a range of 25° to 40°. The sidewall of the groove 60 can also have a stepped or other forms of inclined shapes, which can further increase a contact area between the first connection electrode 21 and the sidewall of the groove 60, enhancing the effect of current shunting and lateral injection into the first semiconductor layer 121. However, this patent is not limited thereto, and it can be selected and set according to actual conditions. Furthermore, corresponding grooves 60 can also be set in the embodiments shown in figures such as FIG. 2, FIG. 11, and FIG. 13 to enhance lateral current propagation within the first semiconductor layer 121 and reduce the operating voltage.

### Fifth Embodiment

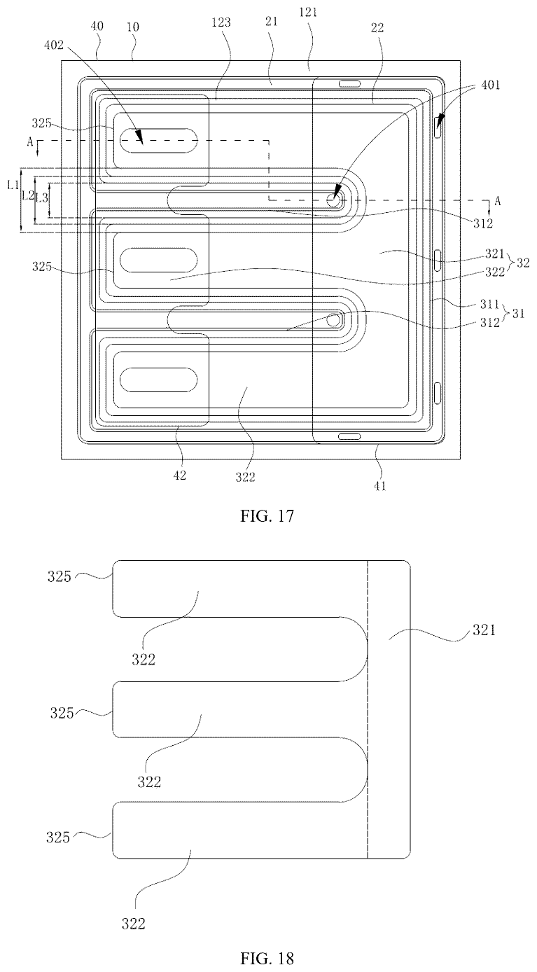

Please refer to FIG. 17, FIG. 17 illustrates a schematic top-view structural view of an LED according to the fifth embodiment of the present disclosure. In this embodiment, in the top-down view of the LED from the upper surface of the LED toward the semiconductor stack 12, as shown in FIG. 18, the second electrode 32 includes a starting electrode 321 and extension electrodes 322. The extension electrodes 322 are connected to the starting electrode 321 and extend in a direction facing away from the starting electrode 321. Second openings 402 are disposed at ends 325 of the extension electrodes 322. The extension electrodes 322 are spaced apart from each other. The extension electrodes 322 can be arranged parallel to each other. This embodiment avoids current crowding at the starting electrode 321 and the extension electrodes 322 by positioning the second openings 402 at the ends 325 of the extension electrodes 322, making the light emission of the LED more uniform.

In some embodiments, in the top-down view of the LED from the upper surface of the LED toward the semiconductor stack 12, a first spacing L1 exists between the ends 325 of adjacent two extension electrodes 322. A range of the first spacing L1 is not less than 10 μm, preferably not less than 20 μm, for example, it can be 25 μm, 30 μm, or 35 μm. This ensures that the ends 325 of the extension electrodes 322 below the second openings 402 are disconnected, thereby avoiding current confinement near the second openings 402. Theoretically, current interruption can be achieved as long as this first spacing L1 is greater than 0. However, due to limitations in actual manufacturing capabilities, it cannot be made too small. Furthermore, if the first spacing L1 is too small, such as less than 5 μm, an area of the first connection electrode 21 becomes smaller, which would cause an increase in voltage.

In some embodiments, in the top-down view of the LED from the upper surface of the LED toward the semiconductor stack 12, portions of the second connection electrode 22 respectively located below the ends 325 of adjacent two extension electrodes 322 have a second spacing L2 between them. A range of the second spacing L2 is not less than 5 μm, preferably not less than 10 μm, for example, it can be 15 μm, 20 μm, or 25 μm. This further avoids current confinement near the second openings 402 and prevents current crowding. Theoretically, current interruption can be achieved as long as the second spacing L2 is greater than 0. However, due to limitations in actual manufacturing capabilities, it cannot be made too small. Furthermore, if the second spacing L2 is too small, such as less than 5 μm, an area of the first connection electrode 21 becomes smaller, which would cause an increase in voltage. In some embodiments, the first spacing L1 is greater than the second spacing L2.

In some embodiments, in the top-down view of the LED from the upper surface of the LED toward the semiconductor stack 12, portions of the second semiconductor layer 123 respectively located below the ends 325 of adjacent two extension electrodes 322 have a third spacing L3 between them. The second spacing L2 is greater than the third spacing L3. In some embodiments, considering the need to improve light emission efficiency, the second semiconductor layer 123 is appropriately thinned to reduce light absorption, but this reduces the lateral current spreading capability between semiconductor stacks 12. The reduction in lateral spreading capability and the high Al component in a deep ultraviolet LED both cause an increase in contact voltage on an N-side of the LED. Therefore, an N-side electrode (i.e., the first electrode 31) can be designed to surround a periphery of the LED, to thereby form the ring electrode 311, and the strip electrodes 312 can be added and connected inside a light emitting region to reduce voltage. Specifically, in the top-down view of the LED from the upper surface of the LED toward the semiconductor stack 12, the first electrode 31 includes an ring electrode 311 and strip electrodes 312. The ring electrode 311 surrounds the second electrode 32. The strip electrodes 312 are connected to the ring electrode 311 and extend toward the starting electrode 321. Each of the strip electrodes 312 are located between adjacent two extension electrodes 322. At least one first opening 401 is disposed at the end 325 of the strip electrode 312. By positioning the first openings 401 near ends 325 of the strip electrodes 312, current crowding at connection positions between the strip electrodes 312 and the ring electrode 311 can also be avoided, further improving the light emission uniformity of the LED.

In some embodiments, at least one first opening 401 is disposed on the ring electrode 311. Distributing the first openings 401 on both the ring electrode 311 and the strip electrode 312 further improves the light emission uniformity on a side of the first electrode 31. In some embodiments, in the top-down view of the LED from the upper surface of the LED toward the semiconductor stack 12, the extension electrode 322 is elongated, and the second electrode 32 has an “E” shape.

### Sixth Embodiment

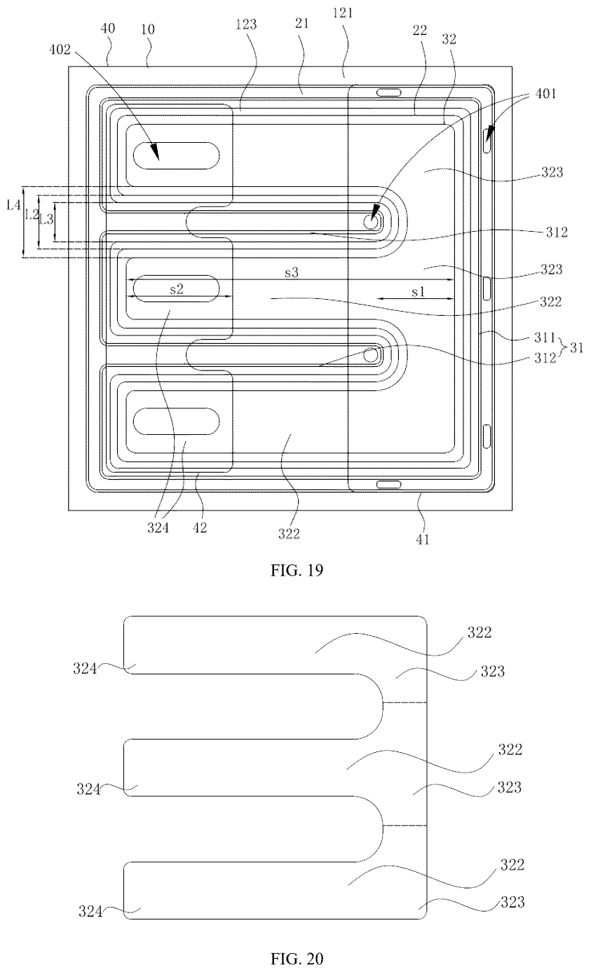

Please refer to FIG. 19, FIG. 19 illustrates a schematic top-view structural view of an LED according to the sixth embodiment of the present disclosure. Main differences between this embodiment and other embodiments are as follows: in the top-down view of the LED from the upper surface of the LED toward the semiconductor stack 12, each extension electrode 322 has a first end 323 and a second end 324 (the first end 323 can be understood as a right end in the FIG. 20, and the second end 324 can be understood as a left end in the FIG. 20). The extension electrode 322 extends along a direction from the first end 323 to the second end 324. The first ends 323 of the extension electrodes 322 are connected to each other. The second ends 324 of the multiple extension electrodes 322 are not connected, that is to say, a fourth spacing L4 exists between the second ends 324 of adjacent two extension electrodes 322. In an embodiment, a range of the fourth spacing L4 is not less than 10 μm, preferably not less than 20 μm, for example, it can be 25 μm, 30 μm, or 35 μm. Theoretically, current interruption can be achieved as long as the fourth spacing L4 is greater than 0. However, due to limitations in actual manufacturing capabilities, it cannot be made too small. Furthermore, if the fourth spacing L4 is too small, such as less than 5 μm, an area of the first connection electrode 21 becomes smaller, which would cause an increase in voltage.

The second opening 402 does not coincide with the first end 323. By positioning the second opening 402 at a non-connected end of the extension electrode 322, current crowding at the first end 323 is avoided, making the light emission of the LED more uniform. In an embodiment, in the top-down view of the LED from the upper surface of the LED toward the semiconductor stack 12, a minimum spacing between the second opening 402 and the first end 323 is not less than one-fifth of an extension length of the extension electrode 322. In some embodiments, the first end 323 extends laterally from a right boundary of the extension electrode 322 toward a left side of the extension electrode 322, and a lateral length s1 of the first end 323 does not exceed one-fifth of a lateral length s3 of the extension electrode 322. The second end 324 extends laterally from a left boundary of the extension electrode 322 toward a right side of the extension electrode 322, and a lateral length s2 of the second end 324 does not exceed one-fifth of the lateral length s3 of the extension electrode 322. In some embodiments, the second opening 402 is disposed at the second end 324 of the extension electrode 322. However, this case is not limited thereto; the second opening 402 may be disposed near the second end 324, or between the first end 323 and the second end 324.

In some embodiments, in the top-down view of the LED from the upper surface of the LED toward the semiconductor stack 12, portions of the second connection electrode 22 respectively located below the second ends 324 of adjacent two extension electrodes 322 have a second spacing L2 between them. A range of the second spacing L2 is not less than 5 μm, preferably not less than 10 μm, for example, it can be 15 μm, 20 μm, or 25 μm. Theoretically, current interruption can be achieved as long as this second spacing L2 is greater than 0. However, due to limitations in actual manufacturing capabilities, it cannot be made too small. Furthermore, if the second spacing L2 is too small, such as less than 5 μm, the area of the first connection electrode 21 becomes smaller, which would cause an increase in voltage. In some embodiments, the first spacing L1 is greater than the second spacing L2.

In some embodiments, in the top-down view of the LED from the upper surface of the LED toward the semiconductor stack 12, portions of the second semiconductor layer 123 respectively located below the second ends 324 of adjacent two extension electrodes 322 have a third spacing L3 between them.

In some embodiments, considering the need to improve light emission efficiency, the second semiconductor layer 123 is appropriately thinned to reduce light absorption, but this reduces the lateral current spreading capability between the semiconductor stacks 12. The reduction in lateral spreading capability and the high Al component in a deep ultraviolet LED both cause an increase in contact voltage on an N-side of the LED. Therefore, an N-side electrode (i.e., the first electrode 31) can be designed to surround the periphery forming the ring electrode 311, and strip electrodes 312 can be added and connected inside a light emitting region to reduce voltage. In the top-down view of the LED from the upper surface of the LED toward the semiconductor stack 12, the first electrode 31 includes a ring electrode 311 and strip electrodes 312. The ring electrode 311 surrounds the second electrode 32. The strip electrodes 312 are connected to the ring electrode 311 and extend toward the first end 323 of the extension electrode 322. The strip electrodes 312 are located between adjacent two extension electrodes 322. At least one first opening 401 coincides with the end 325 of the strip electrode 312.

The present disclosure also provides a light emitting device, which includes an LED. The LED adopts the LED provided in any of the above embodiments, and its specific structure and technical effects will not be repeated here.

Furthermore, those skilled in the art should understand that although many problems exist in the prior art, each embodiment or technical solution of the present disclosure may only be improved in one or several aspects, and does not necessarily need to solve all the technical problems listed in the prior art or the background art simultaneously. Those skilled in the art should understand that content not mentioned in a claim should not be construed as a limitation to that claim.

Finally, it should be noted that: the above embodiments are only used to illustrate the technical solutions of the present disclosure, and are not intended to limit them; although the present disclosure has been described in detail with reference to the foregoing embodiments, those of ordinary skill in the art should understand that: they can still modify the technical solutions described in the foregoing embodiments, or perform equivalent replacements for some or all of the technical features; and these modifications or replacements do not make the essence of the corresponding technical solutions deviate from the scope of the technical solutions of the embodiments of the present disclosure.

What is claimed is:

1. A light emitting diode (LED), comprising:
a semiconductor stack, comprising: a first semiconductor layer, a light emitting layer, and a second semiconductor layer sequentially stacked in that order;
a first electrode, disposed on the semiconductor stack and electrically connected to the first semiconductor layer;
a second electrode, disposed on the semiconductor stack and electrically connected to the second semiconductor layer;
an insulating layer, covering the semiconductor stack, the first electrode, and the second electrode, wherein the insulating layer defines a first opening and a second opening;
a first bonding pad, disposed on the insulating layer, wherein the first bonding pad penetrates through the first opening and is electrically connected to the first electrode; and
a second bonding pad, disposed on the insulating layer, wherein the second bonding pad penetrates through the second opening and is electrically connected to the second electrode;
wherein in a top-down view of the LED from an upper surface of the LED toward the semiconductor stack, the first electrode comprises an ring electrode and at least one strip electrode, each of the strip electrode is spaced apart from the ring electrode, the second electrode comprises at least two extension electrodes, the ring electrode surrounds the second electrode, each of the strip electrode is located between adjacent two extension electrodes of the at least two extension electrodes, the second opening is disposed on a side of the second electrode, an end of each of the strip electrode close to the second opening is defined as a first end, and an end of each of the strip electrode away from the second opening is defined as a second end, at least one the first opening is disposed at the second end of each of the strip electrode.

2. The LED as claimed in claim 1, wherein a number of the at least one strip electrode is a, a number of at least two extension electrodes is b, and b=a+1.

3. The LED as claimed in claim 1, wherein two sides of one of the adjacent two extension electrodes of the at least two extension electrodes are respectively connected to two sides of the other of the adjacent two extension electrodes of the at least two extension electrodes to form a closed-loop pattern.

4. The LED as claimed in claim 3, wherein a number of the closed-loop pattern is two; and in the top-down view of the LED from the upper surface of the LED toward the semiconductor stack, the two closed-loop patterns are connected to form a shape formed by two rectangles sharing one common side.

5. The LED as claimed in claim 1, wherein the LED further comprising: a first connection electrode and a second connection electrode;
wherein the first connection electrode is disposed on the semiconductor stack and is electrically connected to the first electrode, and the second connection electrode is disposed on the semiconductor stack and is electrically connected to the second electrode; and
wherein each of the at least two extension electrodes has a first side away from the second opening and a second side close to the second opening, the first side of one of the adjacent two extension electrodes of the at least two extension electrodes is connected to the first side of the other of the adjacent two extension electrodes of the at least two extension electrodes, and a first spacing exists between the second side of one of the adjacent two extension electrodes of the at least two extension electrodes and the second side of the other of the adjacent two extension electrodes of the at least two extension electrodes.

6. The LED as claimed in claim 5, wherein in the top-down view of the LED from the upper surface of the LED toward the semiconductor stack, a second spacing exists between portions of the second connection electrode respectively located below the second sides of the adjacent two extension electrodes of the at least two extension electrodes.

7. The LED as claimed in claim 6, wherein the first spacing is not less than 10 μm, and the first spacing is greater than the second spacing.

8. The LED as claimed in claim 5, wherein in the top-down view of the LED from the upper surface of the LED toward the semiconductor stack, a third spacing exists between portions of the second semiconductor layer respectively located below the second sides of the adjacent two extension electrodes of the at least two extension electrodes.

9. The LED as claimed in claim 1, wherein in the top-down view of the LED from the upper surface of the LED toward the semiconductor stack, a horizontal minimum spacing exists between the first opening and the second opening, and the horizontal minimum spacing is not less than one-quarter of an extension length of one of the at least two extension electrodes.

10. The LED as claimed in claim 1, wherein each of the at least one strip electrode is provided with a protruding structure at the second end of each of the at least one strip electrode, and at least one the first opening is defined in the protruding structure.

11. The LED as claimed in claim 1, wherein at least one the first opening is disposed on the ring electrode.

12. The LED as claimed in claim 1, wherein in the top-down view of the LED from the upper surface of the LED toward the semiconductor stack, the LED has a first side edge, a second side edge, a third side edge, and a fourth side edge connected sequentially in that order, the first side edge and the third side edge are arranged opposite to each other, the second side edge and the fourth side edge are arranged opposite to each other, the second opening is closer to the fourth side edge than the first opening, and the first opening is closer to the second side edge than the second opening.

13. The LED as claimed in claim 12, wherein in the top-down view of the LED from the upper surface of the LED toward the semiconductor stack, a first minimum spacing from one of the first opening within one of the at least one strip electrode to the second side edge is less than ½ of an extension length of each of the at least two extension electrodes, and greater than 1/10 of the extension length of each of the at least two extension electrodes.

14. The LED as claimed in claim 12, wherein in the top-down view of the LED from the upper surface of the LED toward the semiconductor stack, a second minimum spacing from one of the second opening to the fourth side edge is less than ½ of an extension length of each of the at least two extension electrodes, and greater than 1/15 of the extension length of each of the at least two extension electrodes.

15. The LED as claimed in claim 1, wherein a thickness of the second semiconductor layer is in a range from 1 nm to 100 nm.

16. The LED as claimed in claim 5, wherein in the top-down view of the LED from the upper surface of the LED toward the semiconductor stack, a contact area between the second connection electrode and the second semiconductor layer is at least 45% of an area of the LED.

17. The LED as claimed in claim 1, wherein in the top-down view of the LED from the upper surface of the LED toward the semiconductor stack, an area of the second semiconductor layer is at least 55% of an area of the LED.

18. The LED as claimed in claim 5, wherein in the top-down view of the LED from the upper surface of the LED toward the semiconductor stack, an area ratio of the first connection electrode to the second connection electrode is not greater than 1:4.

19. The LED as claimed in claim 1, wherein the LED is an ultraviolet LED.

20. A light emitting device, comprising the LED as claimed in claim 1.
